(19) United States
(12) Patent Application Publication
(10) Pub. No.: US 2025/0391695 A1
(43) Pub. Date: Dec. 25, 2025

(54) SUBSTRATE TREATMENT APPARATUS

(71) Applicant: Samsung Electronics Co., Ltd., Suwon-si (KR)

(72) Inventors: Woojin Jang, Suwon-si (KR); Kyungsun Kim, Suwon-si (KR); Yirop Kim, Suwon-si (KR); Hyuk Kim, Suwon-si (KR); Junghyun Song, Suwon-si (KR); Seungbin Ahn, Suwon-si (KR); Kuihyun Yoon, Suwon-si (KR); Dongseok Han, Suwon-si (KR); Namkyun Kim, Suwon-si (KR); Yongseok Son, Suwon-si (KR); Yuna Lee, Suwon-si (KR); Woongjin Cheon, Suwon-si (KR)

(21) Appl. No.: 19/024,968

(22) Filed: Jan. 16, 2025

(30) Foreign Application Priority Data
Jun. 25, 2024 (KR) 10-2024-0083035

(51) Int. Cl. H01L 21/683; H01L 21/67

(52) U.S. Cl. CPC H01L 21/6833; H01L 21/67109

(57) ABSTRACT

A substrate treatment device includes an electrostatic chuck, wherein the electrostatic chuck includes a base, an insulating layer arranged on the base, and a through hole penetrating at least a part of each of the base and the insulating layer, the through hole being configured to supply a cooling gas onto the insulating layer, and the insulating layer includes a lower insulation layer, and a plurality of protrusions placed on the lower insulation layer, spaced apart from each other in a horizontal direction, and configured to support a wafer, and at least one of a temperature change of the wafer and a rate of temperature change of the wafer is set by setting a dimension of each of the plurality of protrusions.

### CROSS-REFERENCE TO RELATED APPLICATION

This application is based on and claims priority under 35 U.S.C. § 119 to Korean Patent Application No. 10-2024-0083035, filed on Jun. 25, 2024, in the Korean Intellectual Property Office, the disclosure of which is incorporated by reference herein in its entirety.

### BACKGROUND

The inventive concept relates to a substrate treatment apparatus. More specifically, the inventive concept relates to a substrate treatment apparatus including an electrostatic chuck.

Various semiconductor devices such as processors and memories are manufactured in various process facilities or chambers. In the manufacturing process of semiconductor devices, a chuck for fixing a wafer or substrate to a stage is used. For example, a chuck may include a mechanical chuck using a clamp or vacuum and an electrical chuck using electric force to fix the substrate to the stage. The electrostatic chuck, which is one of the electrical chucks, has the advantage of being simple and having strong adsorption power because the substrate can be fixed to the stage using electrostatic force.

### SUMMARY

Aspects of the inventive concept provide a substrate treatment apparatus capable of easily controlling the temperature of a wafer.

In addition, the task to be solved by the technical idea of the inventive concept is not limited to the above-mentioned task, and other tasks not mentioned above may be clearly understood by those of ordinary skill in the art from the following description.

According to an aspect of the inventive concept, a substrate treatment device includes an electrostatic chuck, wherein the electrostatic chuck includes a base; an insulating layer arranged on the base; and a through hole penetrating at least a part of each of the base and the insulating layer, the through hole being configured to supply a cooling gas onto the insulating layer, and the insulating layer comprises: a lower insulation layer; and a plurality of protrusions placed on the lower insulation layer, spaced apart from each other in a horizontal direction, and configured to support a wafer, and at least one of a temperature change of the wafer and a rate of temperature change of the wafer is set by setting a dimension of each of the plurality of protrusions.

According to another aspect of the inventive concept, a substrate treatment device includes an electrostatic chuck; and a controller configured to control the electrostatic chuck, wherein the electrostatic chuck comprises: a base; and an insulating layer that is placed on the base, the insulating layer including a lower insulating layer and a plurality of protrusions that are placed on the lower insulating layer and configured to support a wafer, and the controller is configured to control a pressure of a cooling gas supplied onto the insulating layer, and change the pressure of the cooling gas during a cycle of a semiconductor process.

According to another aspect of the inventive concept, a substrate treatment device includes an electrostatic chuck; and a controller configured to control the electrostatic chuck, wherein the electrostatic chuck comprises: a base including a coolant channel through which coolant is configured to flow; an insulating layer arranged on the base; an adhesive layer arranged between the base and the insulating layer; and a through hole penetrating at least a part of each of the base, the adhesive layer, and the insulating layer, the through hole being configured to supply a cooling gas onto the insulating layer, the insulating layer comprises: a lower insulating layer; and a plurality of protrusions placed on the lower insulation layer, spaced apart from each other in a horizontal direction, and configured to support a wafer, at least one of a temperature change of the wafer and a rate of temperature change of the wafer is set by setting a dimension of each of the plurality of protrusions, and the controller is configured to control a pressure of a cooling gas input into a space defined by the lower insulating layer and the plurality of protrusions, and change the pressure of the cooling gas during a cycle of a semiconductor process.

According to another aspect of the inventive concept, a method of processing a semiconductor wafer includes positioning the wafer on a plurality of protrusions of an electrostatic chuck of a substrate treatment device; while the wafer is positioned on the plurality of protrusions, supplying a cooling gas at a first pressure to a space under the wafer and between adjacent protrusions of the plurality of protrusions; and while the wafer is positioned on the plurality of protrusions, changing a pressure of the supplied cooling gas from the first pressure to a second pressure different from the first pressure

### BRIEF DESCRIPTION OF THE DRAWINGS

Embodiments will be more clearly understood from the following detailed description taken in conjunction with the accompanying drawings in which:

FIG. 1 is a cross-sectional view illustrating a substrate treatment apparatus according to an embodiment;

FIG. 2 is an enlarged view illustrating an area A of FIG. 1 according to an embodiment;

FIGS. 3 and 4 are graphs illustrating a change in pressure of a supplied cooling gas over time according to an embodiment;

FIG. 5 is a graph showing a thermal variable amount of a wafer according to a contact ratio of protrusions to the wafer according to an embodiment;

FIG. 6 is a graph showing a thermal variable rate of a wafer according to a flow rate of the cooling gas according to an embodiment;

FIGS. 7 and 8 are graphs illustrating a temperature of a wafer according to a pressure change according to an embodiment; and

FIGS. 9 to 12 are cross-sectional views illustrating a process of manufacturing a semiconductor device using a substrate treatment apparatus according to an embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted. In the following drawings, the thickness or size of each layer is exaggerated for convenience and clarity of explanation, and accordingly, may be slightly different from the actual shape and ratio.

As used herein, the terms “continuity”, “in continuity”, and “integrally formed” may refer to structures, patterns, and/or layers that are formed at the same time and of the same material, without a break in the continuity of the material of which they are formed. As one example, structures, patterns, and/or layers that are in “continuity” or “integrally formed” may be homogeneous monolithic structures.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

An item, layer, or portion of an item or layer described as “extending” or as extending “lengthwise” in a particular direction has a length in the particular direction and a width perpendicular to that direction, where the length is greater than the width.

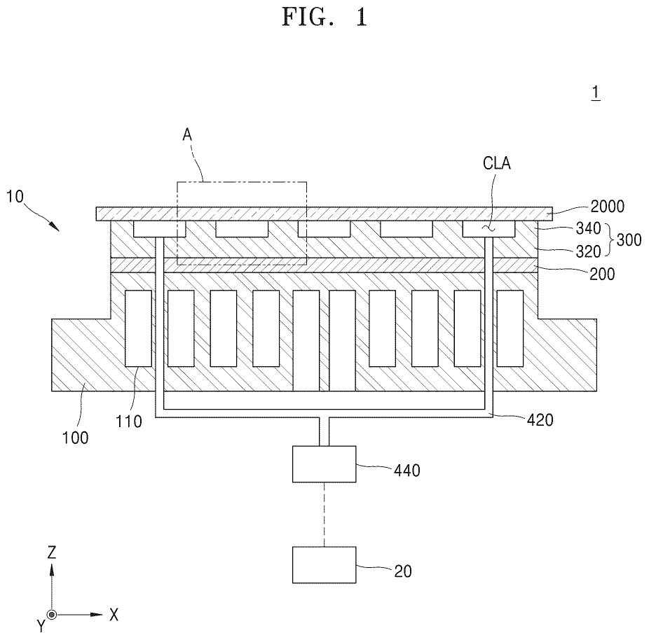

FIG. 1 is a cross-sectional view illustrating a substrate treatment apparatus according to an embodiment.

Referring to FIG. 1, a substrate treatment apparatus 1 may include an electrostatic chuck 10 adsorbing a wafer 2000 and a control unit 20 (e.g., a controller) controlling the electrostatic chuck 10.

The electrostatic chuck 10 may include a base 100, an adhesive layer 200, and a dielectric layer 300. The electrostatic chuck 10 may adsorb and support the wafer 2000. The electrostatic chuck 10 supports the wafer 2000 and may prevent the cooling gas from leaking from under the wafer 2000.

The base 100 is arranged in a lower region of the electrostatic chuck 10 and may support components of the electrostatic chuck 10. The base 100 may have a circular shape or a disk shape made of a metal such as aluminum (Al), titanium (Ti), stainless steel, tungsten (W), or an alloy thereof.

For cooling the wafer 2000, a cooling channel 110 through which a coolant (e.g., water) flows may be further provided in the base 100. For example, the coolant may include any one or more of water, ethylene glycol, silicone oil, liquid Teflon, a mixture of water and glycol, and the like. The cooling water channel 110 may have a concentric or spiral pipe structure centered on the central axis of the base 100.

The adhesive layer 200 may be arranged between the base 100 and the dielectric layer 300. The adhesive layer 200 is formed on the base 100, and the dielectric layer 300 may be disposed on the base 100 by the adhesive layer 200. For example, the adhesive layer 200 may include silicon, acrylic, epoxy, polyimide, or the like. For example, the adhesive layer 200 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), or alloys thereof.

The dielectric layer 300 may be disposed in an upper region of the electrostatic chuck 10. The dielectric layer 300 may support the wafer 2000. The dielectric layer 300 may include ceramic, for example, an aluminum oxide (Al₂O₃) layer, an aluminum nitride (AlN) layer, an yttrium oxide (Y₂O₃) layer or a resin, for example, a dielectric such as polyimide. The dielectric layer 300 may have a circular shape or a disk shape.

The dielectric layer 300 may include a lower dielectric layer 320 and protrusions 340. The lower dielectric layer 320 may be disposed in a lower region of the dielectric layer 300, and may be disposed on the adhesive layer 200. The lower dielectric layer 320 may be disposed to completely cover the adhesive layer 200. In addition, the lower dielectric layer 320 may have a substantially uniform vertical thickness. The top surface of the lower dielectric layer 320 may have a flat shape. In one embodiment, the lower dielectric layer 320 and the protrusions 340 are formal divisions for convenience of description, and the lower dielectric layer 320 and the protrusions 340 may be integrally formed. In another embodiment, the lower dielectric layer 320 and the protrusions 340 may be separately formed.

The lower dielectric layer 320 and the wafer 2000 may be spaced apart from each other in the vertical direction (Z direction) so that a cooling material (e.g., a cooling gas) for cooling the wafer 2000 may be filled between the lower dielectric layer 320 and the wafer 2000. Therefore, an empty space may be formed between the lower dielectric layer 320 and the wafer 2000. The cooling material for cooling the wafer 2000 may be provided in a gaseous state. For example, the cooling material may include helium (He).

The protrusions 340 may be disposed in an upper region of the dielectric layer 300 and may be disposed on the lower dielectric layer 320. A plurality of protrusions 340 may be provided, but a single protrusion 340 may be provided as needed. The protrusions 340 may include the same material as the lower dielectric layer 320. In addition, the protrusions 340 may be formed by the same process as the lower dielectric layer 320. The protrusions 340 may be in contact with the wafer 2000 to support the wafer 2000, and may provide a space for the cooling gas to convect under the wafer 2000. That is, a cooling gas, such as helium gas, may be supplied and convected into a space defined by the lower dielectric layer 320, the protrusions 340, and the wafer 2000. The space may be referred to as a cooling gas space CLA.

In this case, the wafer 2000 may be supported by the plurality of protrusions 340. In an embodiment, the plurality of protrusions 340 may be disposed to be spaced apart from each other in a horizontal direction (X direction and/or Y direction as shown, e.g., in FIG. 1).

In this specification, a direction parallel to the main surface of the wafer 2000 is defined as a horizontal direction (X direction and/or Y direction), and a direction perpendicular to both horizontal directions (X direction and Y direction) is defined as a vertical direction (Z direction).

In an embodiment, the dielectric layer 300 may not include a heater heating the wafer 2000. In another embodiment, the dielectric layer 300 may further include a heater heating the wafer 2000.

In addition, the electrostatic chuck 10 may further include a through hole 420 to fill the cooling gas space CLA by supplying the gas for cooling the wafer 2000 to the cooling gas space CLA. Specifically, the electrostatic chuck 10 may include a through hole 420 passing through the base 100, the adhesive layer 200, and the lower dielectric layer 320 to fill the empty space between the lower dielectric layer 320 and the wafer 2000.

In addition, the electrostatic chuck 10 may further include a cooling gas tank 440 for supplying a cooling gas. The cooling gas tank 440 may store the cooling gas. The cooling gas stored in the cooling gas tank 440 may be supplied to the lower portion of the wafer 2000 through the through hole 420 under the control by the control unit 20.

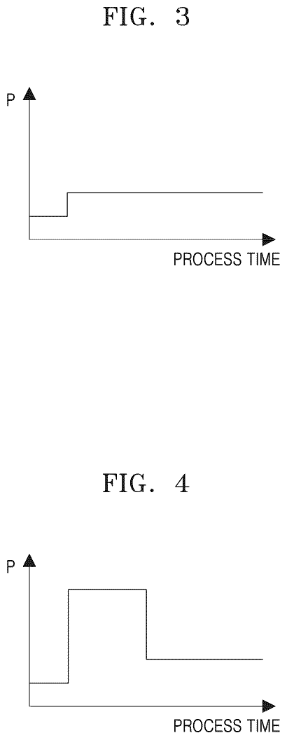

The control unit 20 may control operations of the components of the electrostatic chuck 10. In an embodiment, the control unit 20 may control the supply of the cooling gas to the space defined by the lower dielectric layer 320, the protrusions 340, and the wafer 2000. For example, the control unit 20 may control the pressure of the cooling gas supplied to the space. A method of controlling the pressure of the cooling gas by the control unit 20 is described in more detail with reference to FIGS. 3 and 4.

The control unit 20 may be implemented by hardware, firmware, software, or any combination thereof. For example, the control unit 20 may be a computing device such as a workstation computer, a desktop computer, a laptop computer, or a tablet computer. For example, the control unit 20 may include memory devices such as Read Only Memory (ROM) and Random Access Memory (RAM), and a processor configured to perform predetermined operations and algorithms, such as a microprocessor, a central processing unit (CPU), and a graphics processing unit (GPU). In addition, the control unit 20 may include a receiver and a transmitter for receiving and transmitting electrical signals.

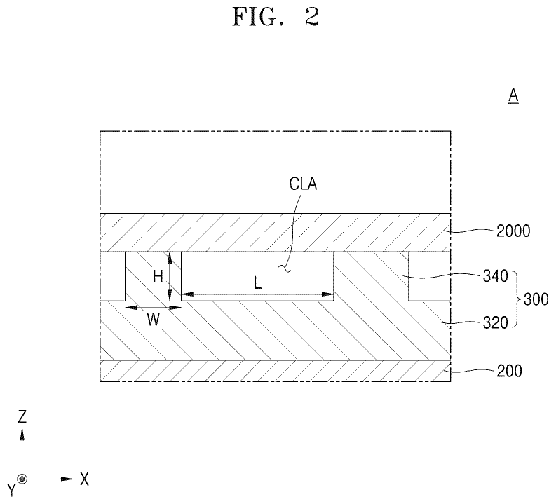

FIG. 2 is an enlarged view illustrating an area A of FIG. 1 according to an embodiment. Description will be made with reference to FIG. 2 together with FIG. 1.

Referring to FIG. 2, a space defined by the lower dielectric layer 320, the protrusions 340, and the wafer 2000 is illustrated. As described above, the space may be referred to as a cooling gas space CLA. The temperature of the wafer 2000 may be easily controlled by increasing the thermal variable amount (e.g., temperature change) of the wafer 2000 and/or increasing the thermal variable rate (e.g., rate of temperature change) of the wafer 2000. For example, the thermal variable amount of the wafer 2000 may be the amount by which the temperature of the wafer 2000 changes at a time when the control unit 20 adjusts a pressure of the cooling gas being supplied to the cooling gas space CLA. For example, the thermal variable rate of the wafer 2000 may be the rate of change of the temperature of the wafer 2000 at a time when the control unit 20 adjusts a pressure of the cooling gas being supplied to the cooling gas space CLA.

First, a thermal variable amount of the wafer 2000 may be calculated based on the volume of the cooling gas space CLA. The thermal variable amount of the wafer 2000 may be calculated by Equation 1 below.

$$Δ T ∝ \frac{{V}_{gas}}{{V}_{total}} = \frac{H * ( 1 - Contact Ratio )}{0.1} \qquad [ Equation 1 ]$$

In the above equation, ΔT represents the thermal variable amount of the wafer 2000, Vₜₒₜₐₗ represents the volume of the dielectric layer 300, V_{gas} represents the volume of the cooling gas, H represents the heights of the protrusions 340, and the contact ratio represents the contact ratio of the protrusions 340 to the wafer 2000. The contact ratio of the protrusions 340 to the wafer 2000 may be calculated as the horizontal surface area of the top surfaces of the protrusions 340 compared to the horizontal surface area of the top surface of the lower dielectric layer 320.

Referring to Equation 1, as the volume of the cooling gas increases, the thermal variable amount of the wafer 2000 may increase. Conversely, as the volume of the cooling gas decreases, the thermal variable amount of the wafer 2000 may decrease.

In addition, the thermal variable amount of the wafer 2000 may be calculated based on the contact area between the cooling gas space CLA and the wafer 2000. In an embodiment, as the contact area between the cooling gas space CLA and the wafer 2000 increases, a thermal variable amount of the wafer 2000 may increase. Conversely, as the contact area between the cooling gas space CLA and the wafer 2000 decreases, the thermal variable amount of the wafer 2000 may decrease.

As the contact area between the cooling gas space CLA and the wafer 2000 increases, the contact area between the protrusions 340 and the wafer 2000 may decrease, and conversely, as the contact area between the cooling gas space CLA and the wafer 2000 decreases, the contact area between the protrusions 340 and the wafer 2000 may increase. Accordingly, as the contact area between the protrusions 340 and the wafer 2000 increases, the thermal variable amount of the wafer 2000 may decrease. Conversely, as the contact area between the protrusions 340 and the wafer 2000 decreases, the thermal variable amount of the wafer 2000 may increase.

For example, the thermal variable amount of the wafer 2000 may be about 6° C. or higher. In addition, the thermal variable rate of the wafer 2000 may be about 2° C./s or more. In addition, the height H of each of the protrusions 340 may be about 10 micrometers or more. In addition, the ratio of the volume of the cooling gas space CLA to the volume of the dielectric layer 300 may be about 9.5% or more. In addition, the contact ratio of the protrusions 340 to the wafer 2000 may be less than or equal to about 6%.

In addition, based on the volume of the cooling gas, the thermal variable rate of the wafer 2000 may be calculated. As the volume of the cooling gas increases, the thermal variable rate of the wafer 2000 may increase, and conversely, as the volume of the cooling gas decreases, the thermal variable rate of the wafer 2000 may decrease.

In an embodiment, as the heights H of the protrusions 340 increase, the thermal variable rate of the wafer 2000 may increase, and as the heights H of the protrusions 340 decrease, the thermal variable rate of the wafer 2000 may decrease.

That is, a contact area with the wafer 2000 by the cooling gas space may be set by appropriately setting dimensions of the protrusions 340. For example, the dimensions of the protrusions 340 may include heights H of the protrusions 340, widths W of the protrusions 340, and/or separation distances L between adjacent protrusions 340. Accordingly, the thermal variable amount of the wafer 2000 may be easily optimized, thereby easily optimizing the substrate treatment process.

In addition, the volume of the cooling gas space CLA may be set by appropriately setting the heights H of the protrusions 340. Therefore, by easily optimizing the thermal variable amount and the thermal variable rate of the wafer 2000, the substrate treatment process may be easily optimized.

FIGS. 3 and 4 are graphs illustrating a change in pressure of a supplied cooling gas over time according to an embodiment. In FIGS. 3 and 4, the horizontal axis represents time and the vertical axis represents pressure. Both the horizontal and vertical axes appear as arbitrary units (a.u.). Description will be made with reference to FIGS. 1 and 2.

Referring to FIGS. 3 and 4, supply pressure of cooling gas provided to a cooling gas space within a cycle of a semiconductor process is illustrated. The cycle may be a repeated cycle of specific operations required in a semiconductor process. The control unit 20 may control the supply pressure of the cooling gas provided to the cooling gas space CLA. The control unit 20 may change the supply pressure of the cooling gas during a cycle. FIG. 3 illustrates that the supply pressure of the cooling gas is changed once during the cycle, and FIG. 4 illustrates that the supply pressure of the cooling gas is changed twice during the cycle. However, the inventive concept is not limited thereto, and the control unit 20 may change the supply pressure of the cooling gas three or more times within one cycle.

The control unit 20 may change the supply pressure of the cooling gas, for example, by adjusting the operating level of a pump or motor that supplies the cooling gas to the cooling gas space CLA, and/or by adjusting one or more valves that may be positioned along the path of the cooling gas between the cooling gas tank 440 and the cooling gas space CLA.

Although FIG. 3 illustrates, by way of example, that the supply pressure of the cooling gas increases, the inventive concept is not limited thereto, and the control unit 20 may reduce the supply pressure of the cooling gas. Likewise, although FIG. 4 shows, by way of example, that the supply pressure of the cooling gas decreases after increasing, the inventive concept is not limited thereto, and the control unit 20 may variously change the supply pressure of the cooling gas. For example, the control unit 20 may increase the supply pressure of the cooling gas twice, reduce the supply pressure of the cooling gas twice, and/or reduce the supply pressure of the cooling gas and then increase the supply pressure of the cooling gas again.

In addition, the thermal variable amount of the wafer 2000 may be controlled according to the amount of change in the supply pressure of the cooling gas. In an embodiment, as the amount of change in the supply pressure of the cooling gas increases, the change in the thermal variable amount of the wafer 2000 may increase. Conversely, as the amount of change in the supply pressure of the cooling gas decreases, the change in the thermal variable amount of the wafer 2000 may decrease. Accordingly, the control unit 20 may control the supply pressure of the cooling gas to easily control the thermal variable amount of the wafer 2000.

The substrate treatment apparatus 1 of the inventive concept may change the supply pressure of the cooling gas within one cycle so that the temperature of the wafer 2000 may quickly reach a saturated state. The control unit 20 may control the supply pressure of the cooling gas more than once within one cycle so that the temperature of the wafer 2000 may quickly reach a saturated state.

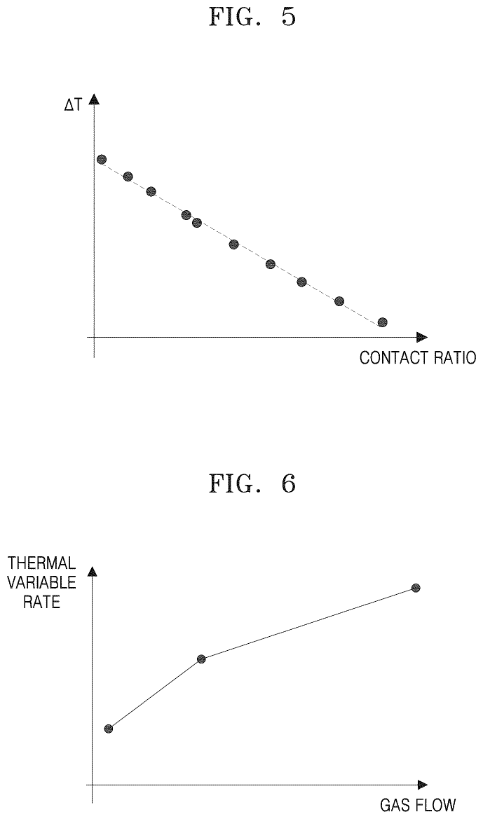

FIG. 5 is a graph showing a thermal variable amount of a wafer according to a contact ratio of protrusions to the wafer according to an embodiment. FIG. 6 is a graph showing a thermal variable rate of a wafer according to a flow rate of the cooling gas according to an embodiment. In FIG. 5, the horizontal axis represents the contact ratio of the protrusions 340 to the wafer 2000, and the vertical axis represents the thermal variable amount of the wafer 2000. In FIG. 6, the horizontal axis represents the flow rate of the cooling gas, and the vertical axis represents the thermal variable rate of the wafer 2000. In FIGS. 5 and 6, both the horizontal axis and the vertical axis appear as arbitrary units (a.u.).

Referring to FIG. 5, as the contact ratio of the protrusions 340 to the wafer 2000 increases, the thermal variable amount of the wafer 2000 may decrease. Conversely, as the contact ratio of the protrusions 340 to the wafer 2000 increases, the thermal variable amount of the wafer 2000 may increase. As described above, as the contact area of the protrusions 340 to the wafer 2000 increases, the contact area of the cooling gas to the wafer 2000 may decrease. That is, as the contact area of the cooling gas with respect to the wafer 2000 increases, the thermal variable amount of the wafer 2000 may increase, and as the contact area of the cooling gas with respect to the wafer 2000 decreases, the thermal variable amount of the wafer 2000 may decrease.

Referring to FIG. 6, as the flow rate of the cooling gas increases, the thermal variable rate of the wafer 2000 may increase. Conversely, as the flow rate of the cooling gas decreases, the thermal variable rate of the wafer 2000 may decrease. The flow rate of the cooling gas may be proportional to the cross-sectional area of the cooling gas and the rate of the cooling gas. The flow rate of the cooling gas may be calculated by Equation 2.

$$Q = A \times V \qquad [ Equation 2 ]$$

In the above Equation, Q represents the flow rate of the cooling gas, A represents the cross-sectional area of the cooling gas, and V represents the rate of the cooling gas.

When the rate of the cooling gas is constant, the flow rate of the cooling gas may increase as the cross-sectional area of the cooling gas increases. That is, as the contact area between the cooling gas and the wafer 2000 increases, the flow rate of the cooling gas may increase. Therefore, as the contact area between the cooling gas and the wafer 2000 increases, the thermal variable rate of the wafer 2000 may increase. Conversely, when the rate of the cooling gas is constant, the flow rate of the cooling gas may decrease as the cross-sectional area of the cooling gas decreases. That is, as the contact area between the cooling gas and the wafer 2000 decreases, the flow rate of the cooling gas may decrease. Therefore, as the contact area between the protrusions 340 and the wafer 2000 decreases, the thermal variable rate of the wafer 2000 may decrease.

As described above, as the contact area between the cooling gas and the wafer 2000 increases, the thermal variable amount of the wafer 2000 and/or the thermal variable rate of the wafer 2000 may increase. Conversely, as the contact area between the cooling gas and the wafer 2000 decreases, the thermal variable amount of the wafer 2000 and/or the thermal variable rate of the wafer 2000 may decrease. That is, as the contact area between the protrusions 340 and the wafer 2000 decreases, the thermal variable amount of the wafer 2000 and/or the thermal variable rate of the wafer 2000 may increase. In addition, as the contact area between the protrusions 340 and the wafer 2000 increases, the thermal variable amount of the wafer 2000 and/or the thermal variable rate of the wafer 2000 may decrease.

As miniaturization, multifunctionalization, and high performance of electronic products are desirable, high-capacity semiconductor devices are desirable, and it becomes important to increase integration to provide high-capacity semiconductor devices. In this way, as the integration of semiconductor devices increases, the design rules for semiconductor device components decrease, and high aspect ratio patterns are used. In the manufacturing process of highly miniaturized semiconductor devices, it is becoming increasingly difficult to form high aspect ratio patterns due to defects in etching profiles, etc.

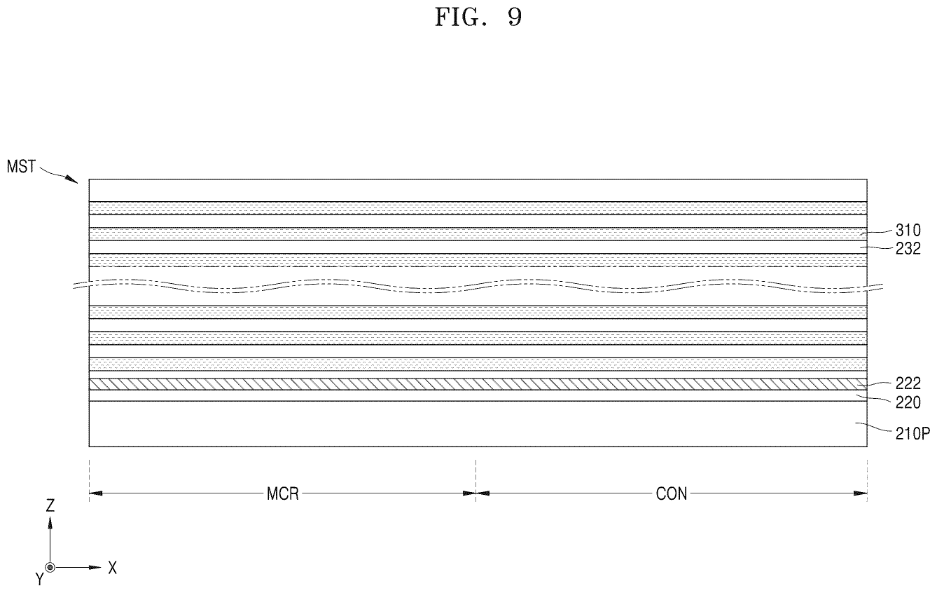

The substrate treatment apparatus 1 according to the inventive concept may easily control the wafer 2000 by increasing the thermal variable amount of the wafer 2000 and/or increasing the thermal variable rate of the wafer 2000. An example of a semiconductor device manufactured by the substrate treatment apparatus 1 is described with reference to FIGS. 9 to 12.

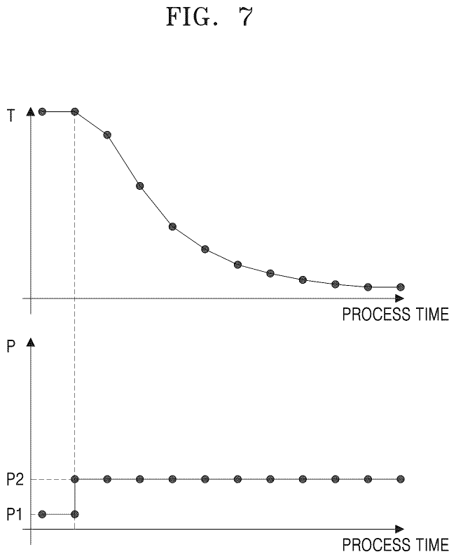

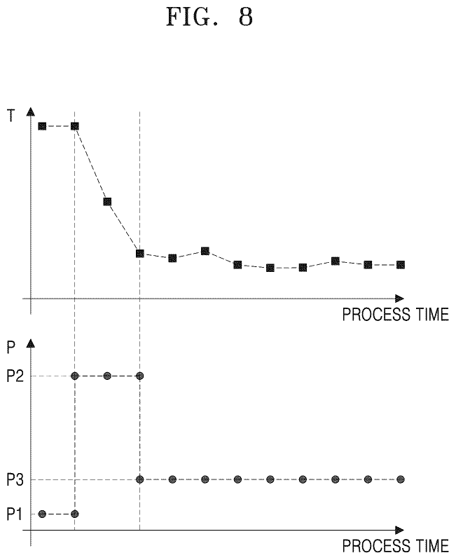

FIGS. 7 and 8 are graphs illustrating a temperature of a wafer according to a pressure change according to an embodiment. In FIGS. 7 and 8, the horizontal axis represents time, and the vertical axis represents the temperature of the wafer 2000 and the pressure of the cooling gas. In FIGS. 7 and 8, both the horizontal axis and the vertical axis appear as arbitrary units (a.u.). In FIGS. 7 and 8, the same positions on the horizontal axis are aligned with each other to indicate the same time.

Referring to FIGS. 7 and 8, the pressure of the cooling gas may change within one cycle of the semiconductor process. FIG. 7 illustrates, by way of example, that the supply pressure of the cooling gas changes once in one cycle, and FIG. 8 illustrates, by way of example, that the supply pressure of the cooling gas changes twice in one cycle.

In FIG. 7, the supply pressure of the cooling gas may change from a first pressure P1 to a second pressure P2. The second pressure P2 may be greater than the first pressure P1. When the supply pressure of the cooling gas increases, the thermal variable rate of the wafer 2000 may increase. That is, the thermal variable rate of the wafer 2000 may be controlled by controlling the supply pressure of the cooling gas.

FIG. 8 illustrates that the supply pressure of the cooling gas changes from a first pressure P1 to a second pressure P2 and from the second pressure P2 to a third pressure P3. The second pressure P2 may be greater than each of the first pressure P1 and the third pressure P3. In addition, the third pressure P3 may be greater than the first pressure P1. By changing the first pressure P1 to the second pressure P2, a thermal variable rate of the wafer 2000 may be increased. Thereafter, when the temperature of the wafer 2000 approaches a saturation temperature, the temperature of the wafer 2000 may be stabilized by changing the second pressure P2 to the third pressure P3. That is, after controlling the thermal variable rate of the wafer 2000 by increasing the supply pressure of the cooling gas, the supply pressure of the cooling gas is reduced to stabilize the temperature of the wafer 2000.

A difference between the second pressure P2 and the first pressure P1 in FIG. 7 may be less than a difference between the second pressure P2 and the first pressure P1 in FIG. 8. A thermal variable rate of the wafer 2000 in FIG. 7 may be less than a thermal variable rate of the wafer 2000 in FIG. 8. That is, a thermal variable rate of the wafer 2000 may be calculated based on a pressure change amount. In an embodiment, the larger the amount of change in the supply pressure of the cooling gas, the greater the thermal variable rate of the wafer 2000, and the smaller the amount of change in the supply pressure of the cooling gas, the smaller the thermal variable rate of the wafer 2000.

As may be seen in FIGS. 7 and 8, the supply pressure of the cooling gas may be controlled based on the temperature of the wafer 2000. In addition, as the change in the supply pressure of the cooling gas increases, the thermal variable rate of the wafer 2000 may increase. Conversely, as the change in the supply pressure of the cooling gas decreases, the thermal variable rate of the wafer 2000 may decrease.

FIGS. 9 to 12 are cross-sectional views illustrating a process of manufacturing a semiconductor device using a substrate treatment apparatus according to an embodiment.

Referring to FIG. 9, a buffer insulating layer 220 may be formed on a cell substrate 210P, and an etching stop layer 222 may be formed on the buffer insulating layer 220.

In embodiments, the cell substrate 210P may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. The buffer insulating layer 220 may be formed using silicon oxide. In embodiments, the etching stop layer 222 may be formed using polysilicon.

In addition, a mold stack MST may be formed by alternately forming sacrificial layers 310 and mold insulating layers 232 on the etching stop layer 222 in a cell region MCR and a connection region CON. In some embodiments, the sacrificial layers 310 and the mold insulating layers 232 may be formed using materials having etch selectivity with respect to each other. For example, the sacrificial layers 310 may include silicon nitride, and the mold insulating layers 232 may include silicon oxide.

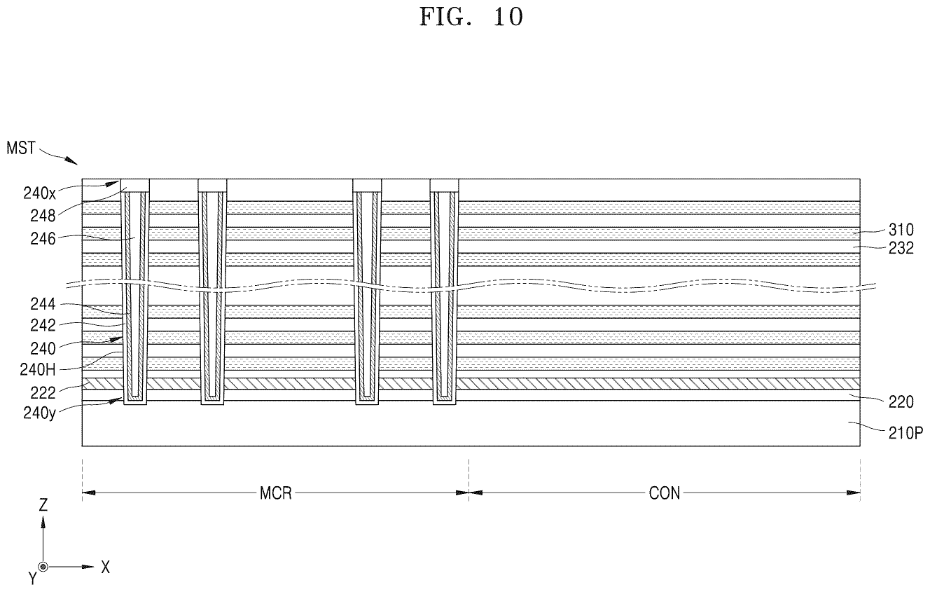

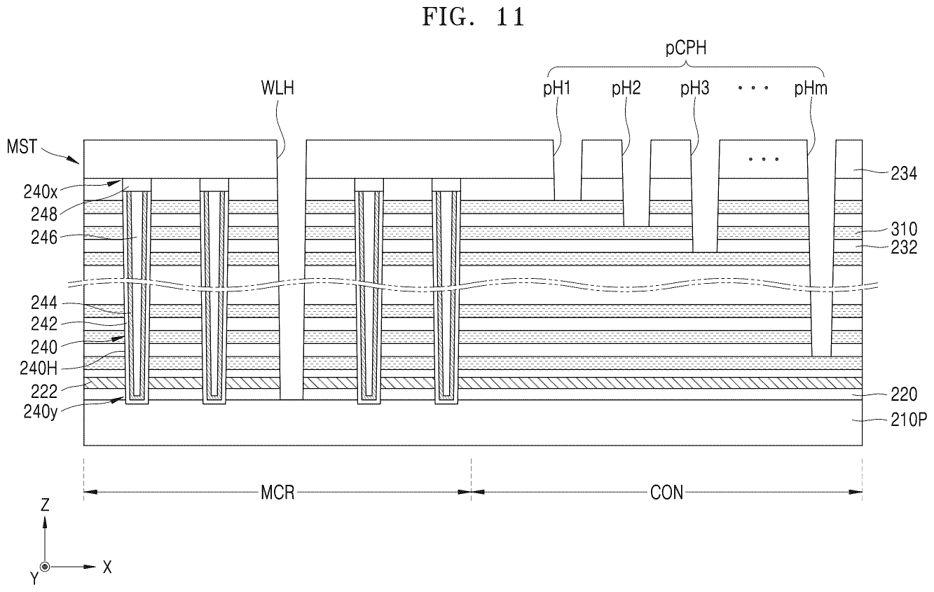

Referring to FIG. 10, a channel structure 240 extending in the vertical direction (Z direction) through the mold stack MST may be formed in the cell region MCR.

In embodiments, in a process of forming the channel structure 240, a channel hole 240H penetrating the mold stack MST may be formed in the cell region MCR. A gate insulating layer 242, a channel layer 244, and a buried insulating layer 246 may be sequentially formed on the inner wall of the channel hole 240H, and a drain region 248 may be formed at the entrance (e.g., at the top) of the channel hole 240H.

In embodiments, the channel hole 240H may extend in a vertical direction (Z direction) through the mold stack MST, the etching stop layer 222, and the buffer insulating layer 220, and a top surface of the cell substrate 210P may be exposed at a bottom portion of the channel hole 240H.

The channel structure 240 has a first end 240x and a second end 240y opposite thereto, and the first end 240x may be arranged adjacent to the top surface of the mold stack MST or at the same vertical level as the top surface of the mold stack MST, and the second end 240y of the channel structure 240 may be arranged to be in contact with the top surface of the cell substrate 210P, and may be arranged at a lower vertical level than the top surface of the cell substrate 210P. In some embodiments, the horizontal width of the first end 240x of the channel structure 240 may be greater than the horizontal width of the second end 240y of the channel structure 240.

Referring to FIG. 11, a stack cover insulating layer 234 may be formed on a top surface of the mold stack MST. The stack cover insulating layer 234 may cover the entire top surface of the mold stack MST in the cell region MCR and the connection region CON. The stack cover insulating layer 234 may have flat top and bottom levels in both the cell region MCR and the connection region CON, and may have a predetermined thickness in both the cell region MCR and the connection region CON.

Thereafter, a stack separation opening WLH extending in the vertical direction (Z direction) through the mold stack MST and the stack cover insulating layer 234 is formed in the cell region MCR and the connection region CON. The stack separation opening WLH may extend in the first horizontal direction (X direction) or the second horizontal direction (Y direction) in the cell region MCR and the connection region CON.

In some embodiments, a dummy channel hole extending in a vertical direction (Z direction) through the mold stack MST may be formed in the connection region CON. In some embodiments, the process of forming the dummy channel hole may be performed simultaneously with an etching process for forming the stack separation opening WLH. In some other embodiments, the process of forming a dummy channel hole may be performed simultaneously with an etching process of forming the channel structure 240.

A plurality of preliminary cell plug holes pCPH extending in the vertical direction (Z direction) may be formed by removing some portions of the stack cover insulating layer 234 and the mold stack MST in the connection region CON. The plurality of preliminary cell plug holes pCPH may have heights that vary in the vertical direction (Z direction). The plurality of preliminary cell plug holes pCPH may have respectively different heights and expose top upper surfaces of corresponding sacrificial layers 310 among the plurality of sacrificial layers 310.

For example, the preliminary cell plug holes pCPH may include a first preliminary hole pH1 exposing the top surface of the uppermost sacrificial layer 310, a second preliminary hole pH2 exposing the top surface of the sacrificial layer 310 directly below the uppermost sacrificial layer 310 (e.g., a second preliminary hole pH2 exposing the top surface of the second uppermost sacrificial layer 310), a third preliminary hole pH3 exposing the top surface of the third sacrificial layer 310 from the uppermost sacrificial layer 310, . . . , and an mth preliminary hole pHm exposing the top surface of the mth sacrificial layer 310 from the uppermost sacrificial layer 310.

The first preliminary hole pH1, the second preliminary hole pH2, . . . , and the mth preliminary hole pHm may be preliminary holes for forming the plurality of cell plug holes CPH later.

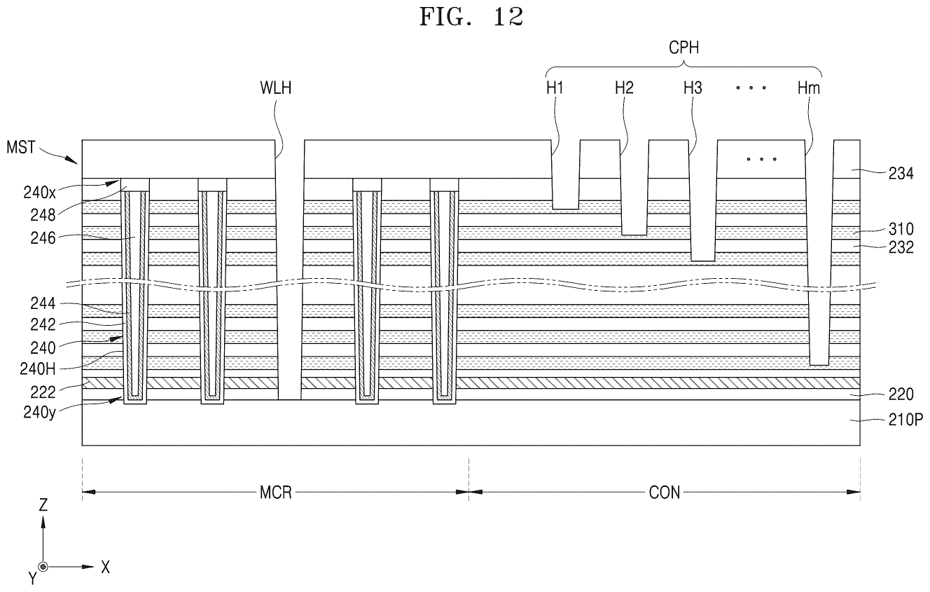

Referring to FIG. 12, a plurality of cell plug holes CPH extending in a vertical direction (Z direction) may be formed by further removing some portions of the stack cover insulating layer 234 and the mold stack MST in the connection region CON based on the plurality of preliminary cell plug holes pCPH. The plurality of cell plug holes CPH may have heights that are different from each other in the vertical direction (Z direction). The plurality of cell plug holes CPH may have respectively different heights and expose top upper surfaces of corresponding sacrificial layers 310 among the plurality of sacrificial layers 310.

For example, the cell plug holes CPH may include a first hole H1 exposing the top surface of the uppermost sacrificial layer 310, a second hole H2 exposing the top surface of the sacrificial layer 310 directly below the uppermost sacrificial layer 310 (e.g., a second hole H2 exposing the top surface of the second uppermost sacrificial layer 310), a third hole H3 exposing the top surface of the third sacrificial layer 310 from the uppermost sacrificial layer 310, . . . , and an mth hole Hm exposing the top surface of the mth sacrificial layer 310 from the uppermost sacrificial layer 310.

Heights of the first hole H1, the second hole H2, . . . , and the mth hole Hm may be greater than heights of the first preliminary hole pH1, the second preliminary hole pH2, . . . , and the mth preliminary hole pHm, respectively.

Then, a cell plug is formed by filling the cell plug hole CPH with a metal material, and a cell structure and a peripheral circuit structure are formed, and accordingly, a semiconductor device may be manufactured.

In the process of manufacturing a semiconductor device, the heights of the plurality of holes H1, H2, . . . , and Hm are different, and a loading effect may occur in the process of forming the plurality of holes H1, H2, . . . , and Hm. The loading effect is an effect of reducing etch uniformity by varying an etching rate depending on the dimensions of a pattern. When the thermal variable amount and/or the thermal variable rate of the wafer 2000 are controlled, the loading effect may be controlled. In an embodiment, when the thermal variable amount of the wafer 2000 increases and/or the thermal variable rate of the wafer 2000 increases, the loading effect may decrease. Therefore, when a semiconductor device is manufactured using the substrate treatment apparatus 1 of the inventive concept, the loading effect is reduced, and thus a highly reliable semiconductor device may be formed.

In addition, even when the heights of the plurality of preliminary holes pH1, pH2, . . . , and pHm of the preliminary cell plug hole pCPH differ before forming the cell plug hole CPH, the cell plug hole CPH and the subsequent cell plug may be formed with high reliability by controlling the temperature of the wafer 2000.

While the inventive concept has been particularly shown and described with reference to embodiments thereof, it will be understood that various changes in form and details may be made therein without departing from the spirit and scope of the disclosure.

1. A substrate treatment device comprising an electrostatic chuck, wherein
the electrostatic chuck comprises:
a base;
an insulating layer arranged on the base; and
a through hole penetrating at least a part of each of the base and the insulating layer, the through hole being configured to supply a cooling gas onto the insulating layer, and
the insulating layer comprises:
a lower insulation layer; and
a plurality of protrusions placed on the lower insulation layer, spaced apart from each other in a horizontal direction, and configured to support a wafer, and
at least one of a temperature change of the wafer and a rate of temperature change of the wafer is set by setting a dimension of each of the plurality of protrusions.

2. The substrate treatment device of claim 1, wherein the dimension of each of the plurality of protrusions is at least one of a height of each of the plurality of protrusions, a width of each of the plurality of protrusions, and a separation distance between adjacent protrusions of the plurality of protrusions.

3. The substrate treatment device of claim 1, wherein a height of each of the plurality of protrusions is about 10 micrometers or more.

4. The substrate treatment device of claim 1, wherein a ratio of a horizontal surface area of the plurality of protrusions to a horizontal surface area of the lower insulating layer is about 6% or less.

5. The substrate treatment device of claim 1, wherein the temperature change of the wafer is about 6° C. or higher.

6. The substrate treatment device of claim 1, wherein the rate of temperature change of the wafer is about 2° C./s or higher.

7. The substrate treatment device of claim 1, wherein the cooling gas includes helium (He).

8. A substrate treatment device comprising:
an electrostatic chuck; and
a controller configured to control the electrostatic chuck, wherein
the electrostatic chuck comprises:
a base; and
an insulating layer that is placed on the base, the insulating layer including a lower insulating layer and a plurality of protrusions that are placed on the lower insulating layer and configured to support a wafer, and
the controller is configured to control a pressure of a cooling gas supplied onto the insulating layer, and change the pressure of the cooling gas during a cycle of a semiconductor process.

9. The substrate treatment device of claim 8, wherein the controller is configured to change the pressure of the cooling gas from a first pressure to a second pressure once during the cycle.

10. The substrate treatment device of claim 9, wherein the second pressure is greater than the first pressure.

11. The substrate treatment device of claim 8, wherein the controller is configured to change the pressure of the cooling gas from a first pressure to a second pressure and change the pressure of the cooling gas from the second pressure to a third pressure during the cycle.

12. The substrate treatment device of claim 11, wherein the second pressure is greater than the first pressure and the third pressure.

13. The substrate treatment device of claim 11, wherein the third pressure is greater than the first pressure.

14. The substrate treatment device of claim 8, wherein the controller is configured to control the pressure of the cooling gas based on a temperature of the wafer.

15. The substrate treatment device of claim 8, further comprising a through hole penetrating at least a part of each of the base and the insulating layer, the through hole being configured to supply the cooling gas onto the insulating layer.

16. The substrate treatment device of claim 8, wherein the cooling gas is configured to be supplied to a space defined by the lower insulating layer, the plurality of protrusions, and the wafer.

17. A substrate treatment device comprising:
an electrostatic chuck; and
a controller configured to control the electrostatic chuck, wherein
the electrostatic chuck comprises:
a base including a coolant channel through which coolant is configured to flow;
an insulating layer arranged on the base;
an adhesive layer arranged between the base and the insulating layer; and
a through hole penetrating at least a part of each of the base, the adhesive layer, and the insulating layer, the through hole being configured to supply a cooling gas onto the insulating layer,
the insulating layer comprises:
a lower insulating layer; and
a plurality of protrusions placed on the lower insulation layer, spaced apart from each other in a horizontal direction, and configured to support a wafer,
at least one of a temperature change of the wafer and a rate of temperature change of the wafer is set by setting a dimension of each of the plurality of protrusions, and
the controller is configured to control a pressure of a cooling gas input into a space defined by the lower insulating layer and the plurality of protrusions, and change the pressure of the cooling gas during a cycle of a semiconductor process.

18. The substrate treatment device of claim 17, wherein the controller is configured to control the at least one of the temperature change and the rate of temperature change of the wafer based on a volume and a horizontal surface area of the space defined by the lower insulating layer and the plurality of protrusions.

19. The substrate treatment device of claim 17, wherein the controller is configured to change the pressure of the cooling gas multiple times during the cycle.

20. The substrate treatment device of claim 17, wherein the controller is configured to raise and lower the pressure of the cooling gas during the cycle.

21-26. (canceled)
